(19) United States
(12) Patent Application Publication
(10) Pub. No.: US 2026/0068399 A1
(43) Pub. Date: Mar. 5, 2026

(54) DISPLAY PANEL AND DISPLAY APPARATUS

(71) Applicant: Tianma Advanced Display Technology Institute (Xiamen) Co., Ltd., Xiamen (CN)

(72) Inventors: Wenqi ZHOU, Xiamen (CN); Zhenyu JIA, Xiamen (CN); Sitao HUO, Xiamen (CN); Tianyi WU, Xiamen (CN)

(73) Assignee: Tianma Advanced Display Technology Institute (Xiamen) Co., Ltd., Xiamen, FJ (CN)

(21) Appl. No.: 19/385,985

(22) Filed: Nov. 11, 2025

(30) Foreign Application Priority Data
Dec. 13, 2024 (CN) 202411844833.6

(51) Int. Cl. H10H 29/853; H10H 29/49; H10H 29/855; H10K 59/126; H10K 59/131; H10K 59/80; H10K 102/00

(52) U.S. Cl. CPC H10H 29/853; H10H 29/49; H10H 29/855; H10K 59/126; H10K 59/131; H10K 59/873; H10K 2102/351

(57) ABSTRACT

A display panel and a display apparatus. The display panel includes a first edge region, a second edge region, an array substrate, light-emitting devices, and an encapsulation layer disposed at a side of the light-emitting devices away from the array substrate. The array substrate includes a substrate and a side trace disposed in the first edge region. The side trace includes a first portion and a second portion electrically connected to each other. The first portion is disposed at a side of the substrate facing the encapsulation layer, and the second portion is disposed at a side of the substrate away from the encapsulation layer. A first encapsulation portion of the encapsulation layer is disposed in the first edge region, and a second encapsulation portion of the encapsulation layer is disposed in the second edge region. The first encapsulation portion has a different shape from the second encapsulation portion.

### CROSS-REFERENCE TO RELATED APPLICATION

The present application claims priority to Chinese Patent Application No. 202411844833.6, filed on Dec. 13, 2024, the content of which is incorporated herein by reference in its entirety.

### TECHNICAL FIELD

The present disclosure relates to the technical field of displaying and, in particular, to a display panel and a display apparatus.

### BACKGROUND

To protect the light-emitting devices in the display panel, an encapsulation layer is typically formed over the light-emitting devices. For example, to prevent scratching of LED chips when bonding a protective film material, an encapsulation layer may be formed over the LED chips. This encapsulation layer may encapsulate the LED chips below it, so that the encapsulation layer protects the LED chips from scratches when bonding the protective film material. However, for ultra-narrow bezel or bezel-less display panels, such as bezel-less display panels within spliced screens, how to design the edge position of the encapsulation layer to ensure the performance of the display panel remains a subject for research.

### SUMMARY

In an aspect, the present disclosure provides a display panel. The display panel includes a first edge region, a second edge region, an array substrate, a plurality of light-emitting devices, and an encapsulation layer disposed at a side of the plurality of light-emitting devices away from the array substrate. The array substrate includes a substrate and a side trace. The side trace is disposed in the first edge region, and includes a first portion and a second portion electrically connected to each other. The first portion is disposed at a side of the substrate facing the encapsulation layer, and the second portion is disposed at a side of the substrate away from the encapsulation layer. A first encapsulation portion of the encapsulation layer is disposed in the first edge region, and the second encapsulation portion is disposed in the second edge region. The first encapsulation portion has a different shape from the second encapsulation portion.

In another aspect, the present disclosure provides a display apparatus. The display apparatus includes a display panel. The display panel includes a first edge region, a second edge region, an array substrate, a plurality of light-emitting devices, and an encapsulation layer disposed at a side of the plurality of light-emitting devices away from the array substrate. The array substrate includes a substrate and a side trace. The side trace is disposed in the first edge region, and includes a first portion and a second portion electrically connected to each other. The first portion is disposed at a side of the substrate facing the encapsulation layer, and the second portion is disposed at a side of the substrate away from the encapsulation layer. A first encapsulation portion of the encapsulation layer is disposed in the first edge region, and the second encapsulation portion is disposed in the second edge region. The first encapsulation portion has a different shape from the second encapsulation portion.

### BRIEF DESCRIPTION OF DRAWINGS

In order to clearly illustrate the technical solutions of embodiments of the present disclosure, the drawings, which are intended to be used in the description of the embodiments, are briefly described as below. It will be apparent that other drawings described below are merely some embodiments of the present disclosure, and other drawings may be obtained by those skilled in the art according to these drawings.

FIG. 1 is a schematic diagram of a display panel according to an embodiment of the present disclosure;

FIG. 2 is a cross-sectional view taken along the A1-A2 direction in FIG. 1 according to an embodiment of the present disclosure;

FIG. 3 is a cross-sectional view taken along the B1-B2 direction in FIG. 1 according to an embodiment of the present disclosure;

FIG. 4 is a cross-sectional view of a display panel related to an embodiment of the present disclosure;

FIG. 5 is a cross-sectional view taken along the A1-A2 direction in FIG. 1 according to an embodiment of the present disclosure;

FIG. 6 is a cross-sectional view taken along the A1-A2 direction in FIG. 1 according to an embodiment of the present disclosure;

FIG. 7 is a cross-sectional view taken along the A1-A2 direction in FIG. 1 according to an embodiment of the present disclosure;

FIG. 8 is a cross-sectional view taken along the A1-A2 direction in FIG. 1 according to an embodiment of the present disclosure;

FIG. 9 is a cross-sectional view taken along the A1-A2 direction in FIG. 1 according to an embodiment of the present disclosure;

FIG. 10 is a schematic diagram of a local portion of FIG. 8 and FIG. 9 according to an embodiment of the present disclosure;

FIG. 11 is a cross-sectional view taken along the C1-C2 direction in FIG. 1 according to an embodiment of the present disclosure;

FIG. 12 is a cross-sectional view taken along the B1-B2 direction in FIG. 1 according to an embodiment of the present disclosure;

FIG. 13 is a cross-sectional view taken along the C1-C2 direction in FIG. 1 according to an embodiment of the present disclosure;

FIG. 14 is a cross-sectional view taken along the B1-B2 direction in FIG. 1 according to an embodiment of the present disclosure;

FIG. 15 is a cross-sectional view taken along the C1-C2 direction in FIG. 1 according to an embodiment of the present disclosure;

FIG. 16 is a cross-sectional view taken along the C1-C2 direction in FIG. 1 according to an embodiment of the present disclosure;

FIG. 17 is a cross-sectional view taken along the C1-C2 direction in FIG. 1 according to an embodiment of the present disclosure;

FIG. 18 is a schematic diagram of a display apparatus according to an embodiment of the present disclosure; and

FIG. 19 is a schematic diagram of a display apparatus according to an embodiment of the present disclosure.

### DESCRIPTION OF EMBODIMENTS

In order to better understand the technical solutions of the present disclosure, embodiments of the present disclosure are described in detail below Referring to the accompanying drawings.

It should be noted that, the described embodiments are merely some but not all of the embodiments of the present disclosure. All other embodiments obtained by those skilled in the art based on the embodiments of the present disclosure shall fall within the scope of the present disclosure.

The terms used in the embodiments of the present disclosure are for the purpose of describing embodiments only, and are not intended to limit the present disclosure. As used in the embodiments and the appended claims of the present disclosure, the singular forms of “a/an” and “the” are intended to include plural forms, unless otherwise clearly specified by the context.

It should be understood that the term “and/or” used herein is merely an association relationship describing an associated object, and indicates that there may be three relationships. For example, A and/or B may indicate: only A, both A and B, and only B. In addition, the symbol “/”′ in the context generally indicates that the relation between the objects in front and at the back of “/” is an “or” relationship.

In the description of the present disclosure, it should be understood that the terms such as “substantially”, “approximate to”, “approximately”, “about”, “roughly”, and “in general” described in the claims and embodiments of the present disclosure mean general agreement within a reasonable process operation range or tolerance range, rather than an exact value.

It should be noted that, although the terms “first” and “second” are used in the embodiments of the present disclosure to describe thresholds, preset values, directions, and the like, they should not be limited to such terms. These terms are merely used to distinguish thresholds, preset values, directions, and the like from each other. For example, without departing from the scope of the embodiments of the present disclosure, a first direction may also be referred to as a second direction, and similarly, a second direction may also be referred to as a first direction. Through in-depth research, the Applicant has provided solutions to the problems in the related art.

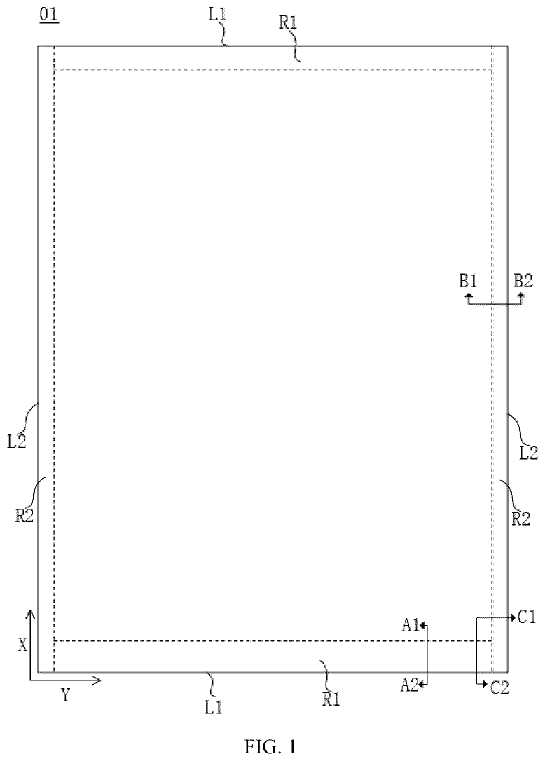

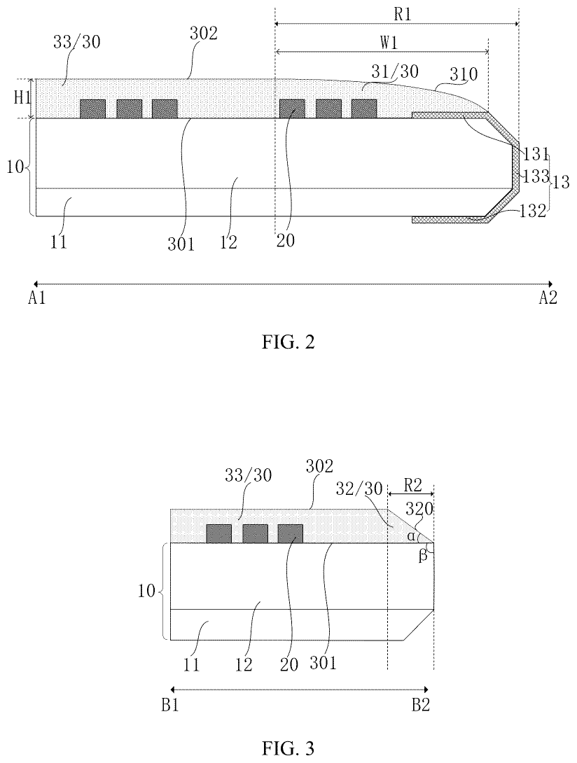

FIG. 1 is a schematic diagram of a display panel according to an embodiment of the present disclosure, FIG. 2 is a cross-sectional view taken along the A1-A2 direction in FIG. 1, and FIG. 3 is a cross-sectional view taken along the B1-B2 direction in FIG. 1.

An embodiment of the present disclosure provides a display panel 01. Referring to FIG. 1, FIG. 2, and FIG. 3, the display panel 01 includes a first edge region R1 and a second edge region R2. The first edge region R1 and the second edge region R2 are both regions of the display panel 01 adjacent to the edges of the display panel 01, and the first edge region R1 and the second edge region R2 may be regions adjacent to different edges of the display panel 01.

For example, as shown in FIG. 1, the display panel 01 includes a first edge L1, and the first edge L1 is disposed at a side of the display panel 01 in a first direction X. The first edge region R1 is a region of the display panel 01 adjacent to the first edge L1. The display panel 01 includes a second edge L2, and the second edge L2 is disposed at a side of the display panel 01 in a second direction Y. The second edge region R2 is a region of the display panel 01 adjacent to the second edge L2. In addition, an edge of the first edge region R1 may coincide with the first edge L1, and an edge of the second edge region R2 may coincide with the second edge L2.

It should be noted that FIG. 1 is merely an illustration of the positional relationship between the first edge L1 and the second edge L2, and the positional relationship between the first edge region R1 and the second edge region R2. The positional relationship between the first edge L1 and the second edge L2, and the positional relationship between the first edge region R1 and the second edge region R2 may take other forms than those shown in FIG. 1. The present disclosure does not impose any limitation thereon.

Referring to FIG. 1, FIG. 2 and FIG. 3, the display panel 01 includes an array substrate 10, a plurality of light-emitting devices 20 and an encapsulation layer 30. The light-emitting devices 20 are disposed at a side of the array substrate 10, and the encapsulation layer 30 is disposed at a side of the light-emitting devices 20 away from the array substrate 10.

The array substrate 10 of the display panel 01 is a substrate for controlling the light-emitting devices 20. The array substrate 10 may include a pixel circuit and a signal line for providing signals to the pixel circuit.

The light-emitting devices 20 are structures configured to emit light in the display panel 01. The light-emitting devices 20 may be organic light-emitting diodes (OLEDs), in which case the light-emitting devices 20 may be fabricated on the array substrate 10 using processes such as evaporation. The light-emitting devices 20 may also be sub-millimeter light-emitting diodes (Mini-LEDs), micro light-emitting diodes (Micro-LEDs), or the like, in which case the light-emitting devices 20 may be coupled to the array substrate 10 via splicing, soldering, or bonding, or other methods.

The encapsulation layer 30 is disposed at a side of the light-emitting devices 20 away from the array substrate 10, and is configured to protect the light-emitting devices 20. On the one hand, it prevents subsequent processes from causing wear to the light-emitting devices 20. On the other hand, it prevents external water and oxygen from penetrating into the light-emitting devices 20 and the array substrate 10, thereby preventing corrosion.

Furthermore, the encapsulation layer 30 is disposed at a side of the light-emitting devices 20 away from the array substrate 10, which may be regarded as being disposed at a side of the light-emitting devices 20 facing the light-emitting surface of the display panel 01. Accordingly, the encapsulation layer 30 is preferably a light-transmitting structure. When the encapsulation layer 30 is a light-transmitting structure, light emitted by the light-emitting devices 20 may be emitted from the light-emitting surface of the display panel 01 after passing through the encapsulation layer 30. In some embodiments, the encapsulation layer 30 may be made of a material that minimizes light loss when transmitting the light emitted by the light-emitting devices 20.

In order for the array substrate 10 to receive and transmit electrical signals so as to drive the light-emitting devices 20, the array substrate 10 needs to be bonded to an IC or a flexible circuit board. When it is desired to ensure that the display panel 01 has a narrow bezel or is bezel-less, the IC and/or flexible circuit board bonded to the array substrate 10 may be bonded to the array substrate 10 at the side thereof away from the light-emitting devices 20.

The array substrate 10 includes a substrate 11 and a driving layer 12 disposed at a side of the substrate 11 facing the encapsulation layer 30. The driving layer 12 may include transistors and/or a pixel circuit, signal line, etc.

In addition, the array substrate 10 further includes a side trace 13. The side trace 13 is configured to electrically connect the signal line disposed at a side of the substrate 11 facing the light-emitting devices 20 to an external electrode disposed at a side of the substrate 11 away from the light-emitting devices 20. The external electrode disposed at the side of the substrate 11 away from the light-emitting devices 20 is configured to bind to the IC and/or the flexible circuit board, thereby enabling the IC and/or flexible circuit board disposed at the side of the substrate 11 away from the light-emitting devices 20 to perform signal interaction with the signal line disposed at the side of the substrate 11 facing the encapsulation layer 30.

Accordingly, the side trace 13 includes a first portion 131 and a second portion 132 electrically connected to each other. The first portion 131 is disposed at the side of the substrate 11 facing the encapsulation layer 30, and the second portion 132 is disposed at the side of the substrate 11 away from the encapsulation layer 30. The side trace 13 may further include a connection portion 133. The connection portion 133 is disposed at a side surface of the array substrate 10 that belongs to the first edge region R1, and the connection portion 133 connects the first portion 131 to the second portion 132. The first portion 131 is configured to electrically connect to at least part of the signal lines disposed at the side of the substrate 11 facing the encapsulation layer 30. For example, the first portion 131 is electrically connected to a transfer electrode disposed at the side of the substrate 11 facing the encapsulation layer 30, and the transfer electrode is connected to at least part of the signal lines disposed at the side of the substrate 11 facing the encapsulation layer 30. The second portion 132 is configured to electrically connect to the external electrode disposed at the side of the substrate 11 away from the encapsulation layer 30, and the external electrode is configured to electrically connect to the IC and/or flexible circuit board disposed at the side of the substrate 11 away from the encapsulation layer 30.

As shown in FIG. 2, the side trace 13 is disposed in the first edge region R1, so that the first edge region R1 includes the side trace 13, while the second edge region R2 does not include the side trace 13. The side trace 13 needs to be routed from the side of the substrate 11 facing the encapsulation layer 30 to the side of the substrate 11 away from the encapsulation layer 30. Due to the presence of the side trace 13, the probability of electrostatic occurrence in the first edge region R1 is significantly greater than the probability of electrostatic damage occurrence in the second edge region R1. Therefore, the first edge region R1 and the second edge region R2 have different electrostatic protection requirements.

In some embodiments of the present disclosure, referring to FIG. 2 and FIG. 3, the encapsulation layer 30 includes a first encapsulation portion 31 and a second encapsulation portion 32. The first encapsulation portion 31 is disposed in the first edge region R1, and the second encapsulation portion 32 is disposed in the second edge region R2. The first encapsulation portion 31 has a different shape from the second encapsulation portion 32. That is, the shape of the portion of the encapsulation layer 30 within the first edge region R1 is different from the shape of the portion of the encapsulation layer 30 within the second edge region R2.

In the technical solution of an embodiment of the present disclosure, according to the electrostatic protection requirements of the first edge region R1 and the second edge region R2, the first encapsulation portion 31 in the first edge region R1 and the second encapsulation portion 32 in the second edge region R2 are designed to be different, so that the first edge region R1 and the second edge region R2 may respectively achieve different electrostatic protection capabilities. Furthermore, by designing the first encapsulation portion 31 and the second encapsulation portion 32 with different shapes, the first edge region R1 and second edge region R2 may have relatively small width while satisfying the different electrostatic protection requirements of the first encapsulation region and second encapsulation region, thereby enabling the display panel 01 to have a narrow bezel or, at least, a bezel-less edge region.

In an embodiment of the present disclosure, as shown in FIG. 2, a surface 310 of the first encapsulation portion 31 away from the array substrate 10 is a curved surface.

In some embodiments of the present disclosure, the surface 310 of the first encapsulation portion 31 away from the array substrate 10 may include a first curved surface portion and a second curved surface portion. In a direction parallel to a plane of the array substrate 10, the first curved surface portion is farther away from the edge of the display panel 01 than the second curved surface portion. Moreover, in a direction perpendicular to the plane of the array substrate 10, the first curved surface portion is farther away from the array substrate 10 than the second curved surface portion.

As shown in FIG. 2, the closer the portion of the first encapsulation portion 31 is to the edge of the display panel 01, the smaller the distance is between the part, corresponding to that portion, of the surface 310 of the first encapsulation portion 31 away from the array substrate 10 and the array substrate 10. That is, in the first edge region R1, the distance between the surface 310 of the first encapsulation portion 31 away from the array substrate 10 and the array substrate 10 gradually decreases along the direction toward the edge of the display panel 01.

Furthermore, as shown in FIG. 2, the encapsulation layer 30 includes a lower surface 301 facing the array substrate 10 and substantially parallel to the plane of the array substrate 10. The encapsulation layer 30 further includes an upper surface 302 away from the array substrate 10 and substantially parallel to the plane of the array substrate 10. The surface of the first encapsulation portion 31 connected between the upper surface 302 and the lower surface 301 may be the surface 310 of the first encapsulation portion 31 away from the array substrate 10, and this surface 310 is a curved surface.

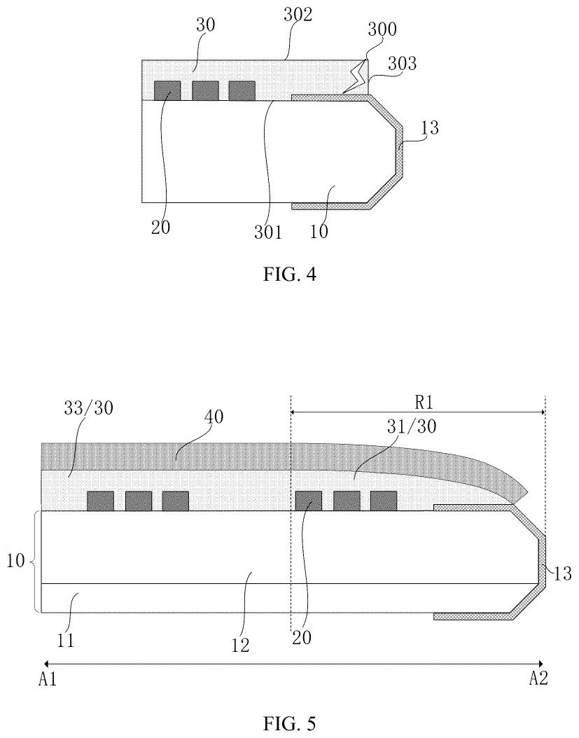

FIG. 4 is a cross-sectional view of a display panel related to an embodiment of the present disclosure.

As shown in FIG. 4, if the encapsulation layer 30 is disposed in the first edge region R1, and the surface 303 connecting the lower surface 301 and the upper surface 302 of the encapsulation layer 30 is a plane perpendicular to the upper surface 302 and the lower surface 301, a sharp corner 300 will be formed between the surface 303 and the upper surface 302 and the lower surface 301 of the encapsulation layer 30. Static electricity tends to accumulate near the sharp corner 300. When the first edge region R1 includes the sharp corner 300, since the first edge region R1 further includes the side trace 13, a conductive path is formed between the side trace 13 in the first edge region R1 and the static electricity near the sharp corner 300. That is, structures in the first edge region R1, including the encapsulation layer 30, are easily damaged by static electricity.

However, in some embodiments of the present disclosure, by configuring the surface 310 of the first encapsulation portion 31 away from the array substrate 10 as a curved surface, the probability of static electricity accumulation in the first edge region R1 is reduced, thereby reducing the risk of static electricity damage to the layer structures, signal lines, devices, etc. in the first edge region R1, and improving the yield of the display panel 01. In addition, by configuring the surface 310 of the first encapsulation portion 31 away from the array substrate 10 as a curved surface, the risk of corner cracking of the first encapsulation portion 31 in the first edge region R1 during processes and/or transportation after the encapsulation layer 30 is formed is reduced.

FIG. 5 is a cross-sectional view taken along the A1-A2 direction in FIG. 1.

As shown in FIG. 5, the display panel 01 may further include a protective film material 40. The protective film material 40 is disposed at a side of the encapsulation layer 30 away from the array substrate 10 to protect the underlying layers from damage. The protective film material 40 and the encapsulation layer 30 may be bonded together by an optical adhesive.

In some embodiments of the present disclosure, since the surface 310 of the first encapsulation portion 31, which has a certain width and away from the array substrate 10, is a curved surface, the protective film material 40 may be better bonded to the first encapsulation portion 31 during the bonding process between the protective film material 40 and the encapsulation layer 30. This prevents the formation of bubbles between the protective film material 40 and the first encapsulation portion 31, which would affect the visual effect of the display panel 01.

In a technical solution corresponding to an embodiment of the present disclosure, the first encapsulation portion 31 may be a self-leveling structure formed by a self-leveling process. That is, after the light-emitting devices 20 are disposed on the array substrate 10, a liquid encapsulation material may be prepared by dripping or coating. The gravity exerted on the encapsulation material and the surface tension of the encapsulation material are utilized to form a smooth curved surface in the first edge region R1. The encapsulation material may be an organic material such as epoxy resin.

Referring to FIG. 2 and FIG. 3, the encapsulation layer 30 further includes a third encapsulation portion 33. The third encapsulation portion 33 is disposed at respective sides of the first edge region R1 and the second edge region R2 away from the edge of the display panel 01. That is, the third encapsulation portion 33 is disposed outside the first edge region R1 and the second edge region R2. The first encapsulation portion 31 and the second encapsulation portion 32 are portions of the encapsulation layer 30 adjacent to the edge of the display panel 01, while the third encapsulation portion 33 may be the portion of the encapsulation layer 30 away from the edge of the display panel 01. Alternatively, the third encapsulation layer 30 is the portion of the encapsulation layer 30 disposed in a middle region of the display panel 01. The third encapsulation layer 30 may be regarded as a conventional portion disposed in the majority area of the display panel 01.

In an embodiment of the present disclosure, as shown in FIG. 2, the first encapsulation portion 31 has a width W1 in a direction parallel to a plane of the substrate 11, which may be regarded as the width of the first encapsulation portion 31 extending in the first edge region R1 from a side of the first edge region R1 away from the edge of the display panel 01 toward the direction of the edge of the display panel 01.

Referring to FIG. 2, the third encapsulation portion 33 has a thickness H1 in a direction perpendicular to the plane of the substrate 11. That is, a conventional portion of the encapsulation layer 30 away from the edge of the display panel 01 has a thickness H1 in the direction perpendicular to the plane of the substrate 11. It should be noted that the structure below the third encapsulation portion 33 does not necessarily have a flat surface, which results in that the surface of the third encapsulation portion 33 facing the array substrate 10 is not necessarily a plane. H1 may be the maximum thickness of the third encapsulation portion 33 in the direction perpendicular to the plane of the substrate 11, the average thickness of the third encapsulation portion 33 in the direction perpendicular to the plane of the substrate 11, or the thickness of the relatively flat region of the third encapsulation portion 33 facing the array substrate 10. The thickness of the third encapsulation portion 33 is usually relatively large. Therefore, H1, regardless of which of the above manners is used for characterization, may basically reflect the overall thickness of the third encapsulation portion 33.

In some embodiments, W1 is greater than or equal to 10*H1. That is, the width of the first encapsulation portion 31 is greater than or equal to 10 times the thickness of the third encapsulation portion 33. The technical solution provided by this embodiment allows the width of the first encapsulation portion 31 to be relatively large. Therefore, when the surface 310 of the first encapsulation portion 31 away from the array substrate 10 is a curved surface, this curved surface may be a curved surface with a relatively gentle curvature, which greatly reduces the risk of sharp tips in the first edge region R1. Furthermore, when the display panel 01 further includes the protective film material 40 bonded to the encapsulation layer 30, the curved surface with the relatively gentle curvature of the first encapsulation portion 31 may result in a high bonding yield between the protective film material 40 and the first encapsulation portion 31. Furthermore, when the first encapsulation portion 31 is fabricated by a self-leveling process, a first encapsulation portion 31 with a larger width is easier to obtain, and the process difficulty is low.

In some embodiments, referring to FIG. 1, FIG. 2, and FIG. 3, the first encapsulation portion 31, the second encapsulation portion 32, and the third encapsulation portion 33 form an integrated structure. Therefore, the first encapsulation portion 31, the second encapsulation portion 32, and the third encapsulation portion 33 are respectively portions of the encapsulation layer 30 disposed at different positions. In this technical solution, the third encapsulation portion 33 is connected to the first encapsulation portion 31 and the second encapsulation portion 32 to form the integrated structure.

In some embodiments, the surface of the first encapsulation portion 31 away from the array substrate 10 may begin to form a curved surface starting from the position connected to the third encapsulation portion 33. Duration the formation of the encapsulation layer 30, the encapsulation material may be dripped near the position of the third encapsulation portion 33 adjacent to the first edge region R1. By controlling the viscosity, dripping amount, and dripping position of the encapsulation material, the shape of the encapsulation material when it spreads to the edge of the display panel 01 may be controlled to form the self-leveling structure.

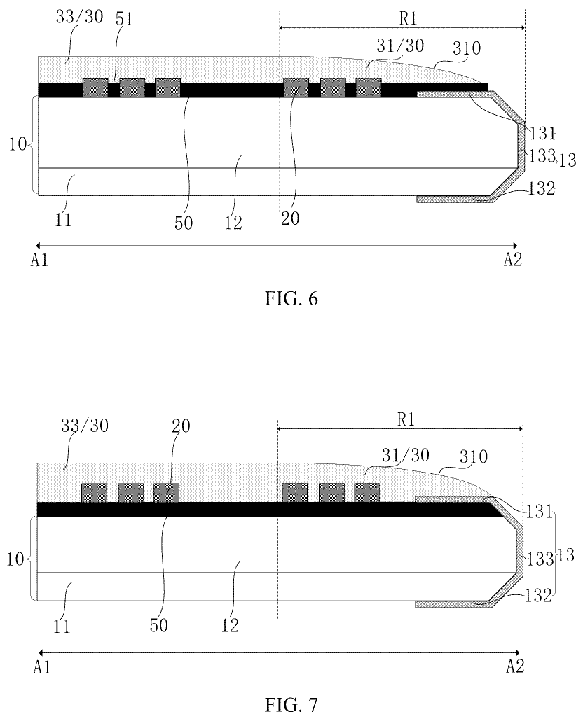

FIG. 6 is a cross-sectional view taken along the A1-A2 direction in FIG. 1.

In an embodiment of the present disclosure, as shown in FIG. 6, the array substrate 10 includes a first layer 50. The first layer 50 is disposed between the encapsulation layer 30 and the substrate 11. The first encapsulation portion 31 is in contact with the first layer 50, and an edge of the first encapsulation portion 31 adjacent to the edge of the display panel 01 is in contact with the first layer 50. For example, when the first edge region R1 shown in FIG. 6 is adjacent to the right edge of the display panel 01, the edge of the first encapsulation portion 31 adjacent to the edge of the display panel 01 shown in FIG. 6 is the right edge of the first encapsulation portion 31.

In some embodiments, the first layer 50 further includes a portion disposed in the first edge region R1, and the portion of the first layer 50 disposed in the first edge region R1 extends further in the direction toward the edge of the display panel 01 relative to the first encapsulation portion 31. Therefore, the surface of the portion of the first layer 50 disposed in the first edge region R1 that is away from the substrate 11 may serve as a supporting surface for the first encapsulation portion 31, thereby allowing the first encapsulation portion 31 to have a relatively flat supporting surface, which is conducive to reducing the probability of forming tips on the fabricated first encapsulation portion 31. When the surface of the first encapsulation portion 31 away from the array substrate 10 is a curved surface, the technical solution provided by embodiments facilitates the formation of this curved surface.

In addition, when the first encapsulation portion 31 is obtained by a self-leveling process, the encapsulation material in the first edge region R1 needs to flow on the first layer 50 to form the self-leveling structure, which makes it easier to obtain a smooth curved surface.

In an embodiment of the present disclosure, the first layer 50 may be a light-shielding layer. The light-shielding layer may reduce the amount of external ambient light entering the array substrate 10, thereby decreasing the reflection of ambient light and improving the display effect of the display panel 01. Meanwhile, the light-shielding layer may avoid changes in the characteristics of the transistors of the array substrate 10 and ensure the driving effect of the display panel 01.

FIG. 7 is a cross-sectional view taken along the A1-A2 direction in FIG. 1.

In some embodiments, as shown in FIG. 7, the first layer 50 may be disposed between the light-emitting devices 20 and the substrate 11. For example, the first layer 50 may be disposed between the light-emitting devices 20 and the driving layer 12, and the driving layer 12 may include transistors and signal lines.

In some embodiments, as shown in FIG. 6, the first layer 50 includes a light-shielding structure 51. The light-shielding structure 51 is disposed at least between adjacent light-emitting devices 20. The light-shielding structure 51 is used to prevent external ambient light from being emitted toward the array substrate 10 through the region between adjacent light-emitting devices 20.

In some embodiments, as shown in FIG. 6, the light-shielding structure 51 in the first layer 50 has a thickness greater than or equal to 5 μm in the direction perpendicular to the plane of the substrate 11. Accordingly, the portion of the first layer 50 disposed in the first edge region R1 also has a thickness greater than or equal to 5 μm in the direction perpendicular to the plane of the substrate 11, and the portion of the first layer 50 disposed in the first edge region R1 is relatively flat. For example, the first layer 50 may be a layer made of an organic material.

In this implementation, when the portion of the first layer 50 disposed in the first edge region R1 is in contact with the first encapsulation portion 31 and supports the first encapsulation portion 31, since the first layer 50 has a relatively large thickness, that is, has a relatively good flatness, the surface of the first encapsulation portion 31 away from the array substrate 10 more easily forms a smooth curved surface, which is also more conducive to preparing the first encapsulation portion 31 as a self-leveling structure using the self-leveling process.

In addition, the optical density of the first light-shielding structure 51 may be less than or equal to 0.4. When the thickness of the light-shielding structure 51 is greater than or equal to 5 μm, even if its optical density is less than or equal to 0.4, its light-shielding effect may still meet the requirements.

Since the light-shielding structure 51 is disposed between the light-emitting devices 20 and has a thickness greater than or equal to 5 μm, the risk of the light-shielding structure 51 climbing onto the light-emitting devices 20 increases during the formation of the first layer 50. If the light-shielding structure 51 climbs onto the light-emitting devices 20, the amount of light emitted by the light-emitting devices 20 and emitted from the light-emitting surface of the display panel 01 will be reduced. However, in this implementation, since the optical density of the light-shielding structure 51 is less than or equal to 0.4, the light-shielding structure 51 that climbs onto the light-emitting devices 20 has little effect on the amount of light emitted by the light-emitting devices 20. Therefore, the light-shielding structure 51 of the display panel 01 according to this implementation has a thickness greater than or equal to 5 μm and the optical density is less than or equal to 0.4, which takes into account both the light-shielding effect of the first layer 50 and the luminous efficiency of the display panel 01.

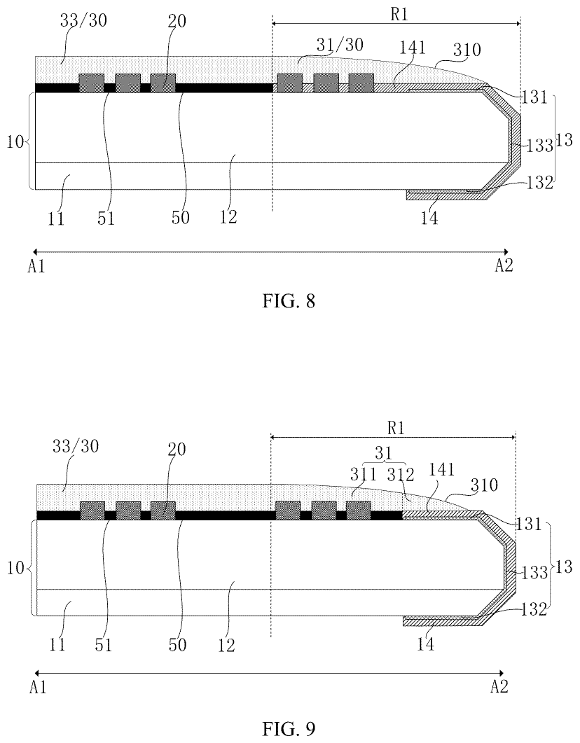

FIG. 8 is a cross-sectional view taken along the A1-A2 direction in FIG. 1, and FIG. 9 is a cross-sectional view taken along the A1-A2 direction in FIG. 1.

In an embodiment of the present disclosure, as shown in FIG. 8 and FIG. 9, the array substrate 10 includes a second layer 14, and the second layer 14 is in contact with the surface of the side trace 13 away from the substrate 11. The second layer 14 may serve as a protective layer to protect the side trace 13. As shown in FIG. 8 and FIG. 9, the second layer 14 includes a portion disposed at a side surface of the display panel 01 and on the same side as the side trace 13, and the second layer 14 includes a portion disposed at the side of the substrate 11 away from the encapsulation layer 30 and a portion disposed at the side of the substrate 11 facing the encapsulation layer 30. For example, as shown in FIG. 8 and FIG. 9, the second layer 14 covers the surface of the side trace 13 that is not in contact with the substrate 11.

In some embodiments, at least a portion of the first encapsulation portion 31 is in contact with the second layer 14. That is, the portion of the second layer 14 disposed at the side of the substrate 11 facing the encapsulation layer 30 is at least disposed in the first edge region R1 and is in contact with at least the portion of the first encapsulation portion 31. As shown in FIG. 8 and FIG. 9, at least a portion of the second layer 14 disposed at the side of the substrate 11 facing the encapsulation layer 30 is disposed between the first encapsulation portion 31 and the first portion 131. Therefore, in the first edge region R1, at least the portion of the second layer 14 serves as a supporting surface for the first encapsulation portion 31.

In some embodiments, the second layer 14 includes a third portion 141, and the third portion 141 is disposed between the substrate 11 and the encapsulation layer 30. Since at least a portion of the first encapsulation portion 31 is in contact with the second layer 14, at least a portion of the third portion 141 is in contact with at least a portion of the first encapsulation portion 31.

An edge of the third portion 141 away from the edge of the display panel 01 is disposed at a side of the first encapsulation portion 31 away from the edge of the display panel 01. For example, when the first edge region R1 shown in FIG. 8 is adjacent to the right edge of the display panel 01, the edge of the third portion 141 shown in FIG. 8 away from the edge of the display panel 01 is the left edge of the third portion 141, and the left edge of the third portion 141 is disposed further to the left relative to the left edge of the first encapsulation portion 31.

In addition, along a direction perpendicular to the plane of the substrate 10, a portion of the third portion 141 may not overlap with the first encapsulation portion 31. For example, as shown in FIG. 8, the portion of the third portion 141 adjacent to the edge of the display panel 01 does not overlap with the first encapsulation portion 31.

In some embodiments, the second layer 14 includes a portion disposed between the first encapsulation portion 31 and the substrate 11, and this portion of the second layer 14 extends further in a direction away from the edge of the display panel 01 relative to the first encapsulation portion 31. Therefore, the surface of the portion of the second layer 14 disposed between the first encapsulation portion 31 and the substrate 11 that is away from the substrate 11 may serve as a supporting surface for the first encapsulation portion 31, thereby allowing the first encapsulation portion 31 to have a relatively flat supporting surface, which is conducive to reducing the probability of forming tips on the fabricated first encapsulation portion 31.

When the surface of the first encapsulation portion 31 away from the array substrate 10 is a curved surface, the technical solution provided by this embodiment facilitates the formation of this curved surface.

In addition, when the first encapsulation portion 31 is obtained by a self-leveling process, the encapsulation material in the first edge region R1 needs to flow on the second layer 14 to form the self-leveling structure, which makes it easier to obtain a smooth curved surface.

In some embodiments, a relatively large distance may also be present between the edge of the third portion 141 away from the edge of the display panel 01 and the edge of the display panel 01, which allows the second layer 14 on the side of the substrate 11 facing the encapsulation layer 30 to effectively protect the side trace 13.

In an embodiment of the present disclosure, as shown in FIG. 9, the array substrate 10 includes the first layer 50, and the first layer 50 is disposed between the encapsulation layer 30 and the substrate 11. The second layer 14 includes the third portion 141, and the third portion 141 is disposed between the substrate 11 and the encapsulation layer 30.

The first encapsulation portion 31 includes a first encapsulation sub-portion 311 and a second encapsulation sub-portion 312. The second encapsulation sub-portion 312 is disposed at a side of the first encapsulation sub-portion 311 adjacent to the edge of the display panel 01. The first encapsulation sub-portion 311 is in contact with the first layer 50, and the second encapsulation sub-portion 312 is in contact with the third portion 141. That is, the portion of the first layer 50 disposed in the first edge region R1 serves as the supporting surface for the portion of the first encapsulation portion 31 relatively away from the edge of the display panel 01. The portion of the second layer 14 disposed at the side of the substrate 11 facing the encapsulation layer 30 and disposed in the first edge region R1 serves as the supporting surface for the portion of the first encapsulation portion 31 relatively adjacent to the edge of the display panel 01.

In some embodiments, portions of the first layer 50 and the second layer 14 are spliced together to serve as the supporting surface for the first encapsulation portion 31. Therefore, a relatively large distance may be provided between the portion of the first layer 50 disposed in the first edge region R1 and the edge of the display panel 01, thereby preventing the first layer 50 from flowing toward the side surface of the display panel 01 and forming an uneven structure. Furthermore, a relatively large distance may also be provided between the edge of the third portion 141 away from the edge of the display panel 01 and the edge of the display panel 01, which enables the second layer 14 on the side of the substrate 11 facing the encapsulation layer 30 to effectively protect the side trace 13.

In some embodiments, as shown in FIG. 9, the surface of the first layer 50 away from the substrate 11 is flush with the surface of the third portion 141 away from the substrate 11. In this technical solution, the distance between the surface of the first layer 50 away from the substrate 11 and the substrate 11 is substantially equal to the distance between the surface of the fourth portion away from the substrate 11 and the substrate 11.

The supporting surface for supporting the first encapsulation portion 31, formed by splicing the first layer 50 and the third portion 141, is a flat structure, which is conducive to reducing the probability of forming tips on the fabricated first encapsulation portion 31. When the surface of the first encapsulation portion 31 away from the array substrate 10 is a curved surface, the technical solution provided by this embodiment facilitates the formation of this curved surface. In addition, when the first encapsulation portion 31 is obtained by a self-leveling process, the encapsulation material in the first edge region R1 needs to flow on this supporting surface to form the self-leveling structure, which makes it easier to obtain a smooth curved surface.

In some embodiments, the difference between a contact angle of the first layer 50 and a contact angle of the second layer 14 is less than a preset value, so that the degree of contact of the encapsulation material with the first layer 50 and the second layer 14 does not differ significantly. For example, the contact angle of the first layer 50 is the same as the contact angle of the second layer 14, the degree of contact of the encapsulation material with the first layer 50 and the second layer 14 is the same.

In some embodiments, the first layer 50 and the second layer 14 are made of the same material, so that the degree of contact of the encapsulation material with the first layer 50 and the second layer 14 is the same.

In some embodiments, the degree of contact of the encapsulation material with the first layer 50 and the second layer 14 does not differ significantly. Therefore, when the encapsulation material forms the encapsulation layer 30, the surface of the first encapsulation portion 31 away from the array substrate 10 tends to form a relatively smooth curved surface. When the first encapsulation portion 31 is obtained by a self-leveling process, the encapsulation material in the first edge region R1 flows on the first layer 50 and the second layer 14 to form the self-leveling structure, which makes it easier to obtain a smooth curved surface.

In an embodiment of the present disclosure, the second layer 14 may be a light-shielding layer, thereby reducing the risk that the side trace 60 is perceived by the human eye. In addition, when the third portion 141 of the second layer 14 serves as the supporting surface for the first encapsulation portion 31 and when the first edge region R1 includes the light-emitting devices 20, the third portion 141 may block external ambient light from entering the array substrate 10.

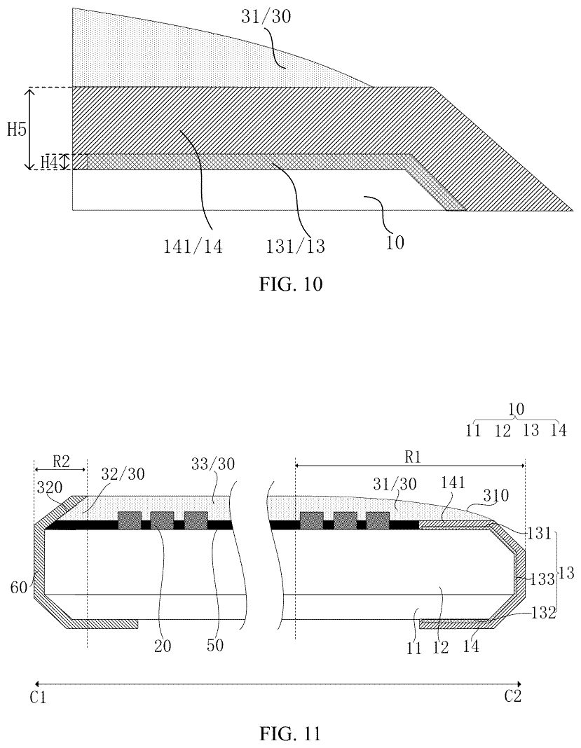

FIG. 10 is a schematic diagram of a local portion of FIG. 8 and FIG. 9.

In an embodiment of the present disclosure, as shown in FIG. 10, the first portion 131 has a thickness H4 in the direction perpendicular to the plane of the substrate 11, and the third portion 141 has a thickness H5 in the direction perpendicular to the plane of the substrate 11, where H5>H4. That is, the thickness of the third portion 141 covering the first portion 131 is greater than the thickness of the first portion 131.

When the third portion 141 serves as at least part of the supporting surface for the first encapsulation portion 31, the flatness of the surface of the third portion 141 facing the first encapsulation portion 31 is affected by the structure below the third portion 141. By setting the thickness of the third portion 141 to be greater than the thickness of the first portion 131 below it, the influence of the first portion 131 on the flatness of the surface of the third portion 141 facing the first encapsulation portion 31 is reduced, that is, the flatness of the surface of the third portion 141 facing the first encapsulation portion 31 is better.

In some embodiments, H5>5*H4. That is, the thickness of the third portion 141 covering the first portion 131 is greater than 5 times the thickness of the first portion 131. When the thickness of the third portion 141 is greater than 5 times the thickness of the first portion 131, the flatness of the surface of the third portion 141 used for supporting the first encapsulation portion 31 is substantially unaffected by the thickness of the first portion 131 below it.

In some embodiments of the present disclosure, the thickness of the first portion 131 along the direction perpendicular to the plane of the substrate 11 is about 1 μm.

In an embodiment of the present disclosure, as shown in FIG. 3, the surface of the second encapsulation portion 32 facing the edge of the display panel 01 is an inclined first plane 320. That is, in the second edge region R2, the side surface connecting the lower surface 301 and the upper surface 302 of the encapsulation layer 30 is an inclined first plane 320. That is, the portion of the encapsulation layer 30 disposed in the second edge region R2 includes a chamfered structure.

In some embodiments, the chamfered structure prevents the encapsulation layer 30 from forming an obvious tip in the second edge region R2. Furthermore, considering the thickness of the encapsulation layer 30, the width of the chamfered structure parallel to the plane of the substrate 11 is not excessively large.

In an embodiment of the present disclosure, as shown in FIG. 3, an angle α is formed between the first plane 320 and the substrate 11, where 30°<<60°. That is, the inclination angle of the first plane 320 is between 30° and 60°.

If the first plane 320 is too flat, its width in the direction parallel to the plane of the substrate 11 is relatively large. In this case, when the encapsulation layer 30 is bonded to the protective film material 40, the protective film material 40 is prone to bond to the first plane 320 of the second encapsulation portion 32. However, due to the chamfered structure of the first plane 320, bubbles are likely to form when the protective film material 40 is bonded to the second encapsulation portion 32, thereby affecting the visual effect of the display panel 01. If the first plane 320 is too steep, there is a greater risk of cracking during fabrication and transportation. When the inclination angle of the first plane 320 is between 30° and 60°, it is neither too flat nor too steep, thereby alleviating the above problems.

FIG. 11 is a cross-sectional view taken along the C1-C2 direction in FIG. 1.

In an embodiment of the present disclosure, as shown in FIG. 11, the array substrate 10 includes a second layer 14, and the display panel 01 further includes a third layer 60. The second layer 14 is in contact with the surface of the first portion 131 away from the substrate 11. As shown in FIG. 11, the second layer 14 may be in contact with the surface of the side trace 13 away from the substrate 11 to protect the side trace 13. The third layer 60 is in contact with at least the side surface of the array substrate 10 in the second edge region R2 and the first plane 320. As shown in FIG. 11, the third layer 60 is attached to the side surface of the array substrate 10 and the first plane.

In an embodiment of the present disclosure, the third layer 60 and the second layer 14 are made of the same material, so that the third layer 60 and the second layer 14 may be prepared using the same material and the same process. Furthermore, both the second layer 14 and the third layer 60 serve as light-shielding layers. The second layer 14 covers the surface of the side trace 13 away from the array substrate 10, which may reduce the risk that the side trace 60 is perceived by the human eye. The third layer 60 may also reduce the risk of reflective structures, such as metal, exposed in the edge region of the second edge region R2 being perceived by the human eye.

In some embodiments, the third layer 60 is conformally attached to the first plane 320. For example, as shown in FIG. 11, after the second encapsulation portion 32 is formed, that is, after the first plane 320 is obtained, the third layer 60 is prepared and a portion of the third layer 60 is conformally deposited on the first plane 320.

In an embodiment of the present disclosure, as shown in FIG. 3 and FIG. 11, in the second edge region R2, the angle between the surface of the array substrate 10 facing the encapsulation layer 30 and the side surface of the array substrate 10 is 90°. That is, the array substrate 10 is not chamfered adjacent to the position of the encapsulation layer 30 in the second edge region R2, but the second encapsulation portion 32 near this position is chamfered, thereby reducing the risk of cracking near this position of the display panel. In addition, if the array substrate 10 is not chamfered adjacent to the position of the encapsulation layer 30 in the second edge region R2, the width of the second edge region R2 is relatively narrow, which is conducive to enabling the display panel 11 to have a narrow bezel or is bezel-less.

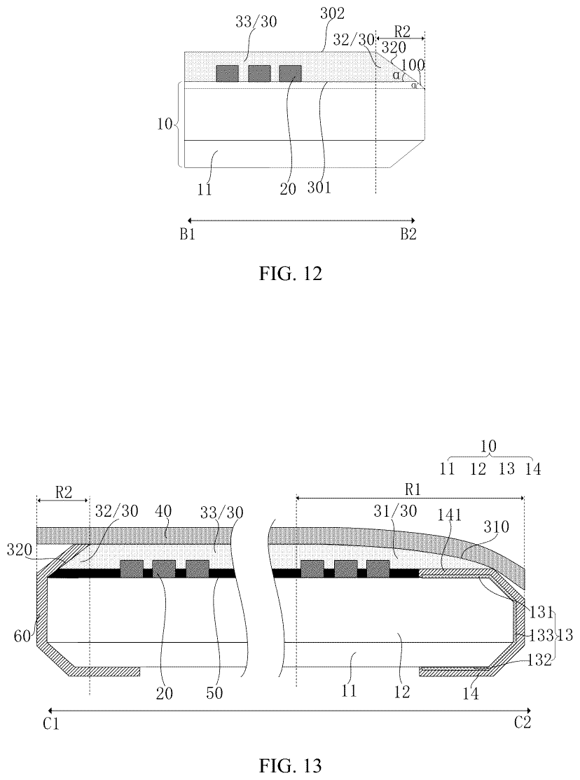

When the angle between the surface of the array substrate 10 facing the encapsulation layer 30 and the side surface of the array substrate 10 is 90°, there is no need to perform cutting, grinding, or other processes for forming a chamfer at this position. This also reduces the layer structure disposed at the side of the substrate 11 of the array substrate 10 facing the encapsulation layer 30, and avoids the gap problem in the second edge region R2 caused by cutting and grinding, thereby ensuring the display effect of the display panel 01. FIG. 12 is a cross-sectional view taken along the B1-B2 direction in FIG. 1.

In an embodiment of the present disclosure, as shown in FIG. 12, in the second edge region R2, the surface of at least part of the layers of the array substrate 10 disposed at the side of the substrate 11 facing the encapsulation layer 30, which faces the edge of the display panel 01, is an inclined second plane 100, and an angle α is formed between the second plane 100 and the substrate 11. For example, as shown in FIG. 12, the second plane 100 and the first plane 320 are disposed in the same plane.

In an embodiment of the present disclosure, in the first edge region R1, the surface between the upper surface of the array substrate 10 facing the encapsulation layer 30 and its side surface is an inclined planar structure. This reduces the risk of disconnection between the portion of the side trace 13 disposed at the side surface of the display panel 01 and the first portion 131.

In addition, in the first edge region R1 and the second edge region R2, the surface between the lower surface of the array substrate 10 away from the encapsulation layer 30 and its side surface may also be an inclined planar structure to reduce the risk of cracking.

It should be noted that the planes involved in the embodiments of the present disclosure refer to planes within the range of process tolerances, i.e., planes that may be obtained with existing process precision.

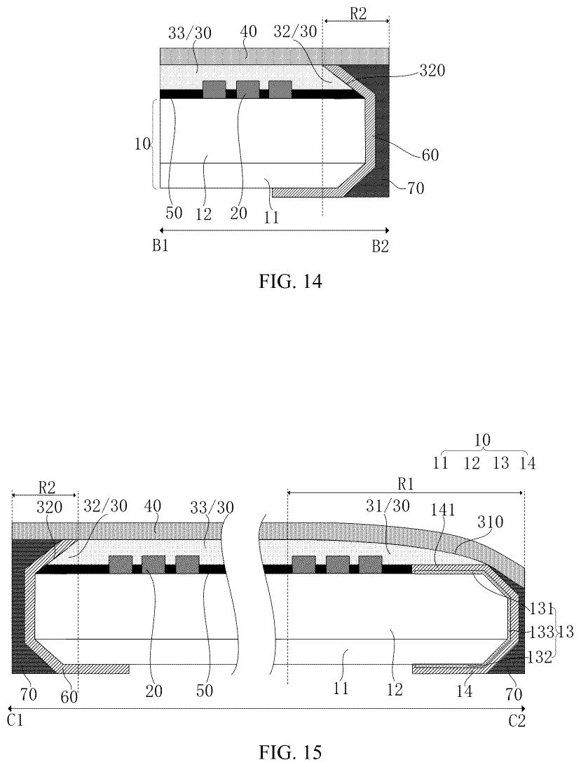

In an embodiment of the present disclosure, as shown in FIG. 11, FIG. 13 and FIG. 14, the width of the first encapsulation portion 31 in the direction parallel to the plane of the substrate 11 is greater than the width of the second encapsulation portion 32 in the direction parallel to the plane of the substrate 11.

In an embodiment of the present disclosure, since the first edge region R1 includes the side trace 13, the first edge region R1 has higher electrostatic protection requirements. The larger the width of the first encapsulation portion 31, the smoother its curved surface, and the lower the likelihood of forming sharp tips. Therefore, increasing the width of the first encapsulation portion 31 allows its structure to better meet the electrostatic protection requirements of the first edge region R1. Furthermore, the bonding difficulty of the protective film material 40 to the first encapsulation portion 31 is lower, and the bonding yield is higher, thereby avoid significant differences in visual effect between the first edge region R1 and other regions as much as possible.

In an embodiment of the present disclosure, since the second edge region R2 does not include the side trace 13, the second edge region R2 has lower electrostatic protection requirements than the first edge region R1. Meanwhile, considering the risk of cracking in the second edge region R2 of the display panel 01, the second encapsulation portion 32 may be configured to include the inclined first plane 320. The inclination angle of the first plane 320 may be relatively large, so that the width of the second encapsulation portion 32 is relatively small. If the width of the second encapsulation portion 32 is large, the light emitted by the light-emitting devices 20, if emitted through the second encapsulation portion 32, will have a significantly different optical path and light intensity relative to other regions. Therefore, by setting the width of the second encapsulation portion 32 relatively small, the impact of variations in the thickness of the encapsulation portion 30 on the light emission effect of the display panel 01 may be minimized. In addition, if the protective film material 40 is not bonded to the second encapsulation portion 32 in the second edge region R2, when the width of the second encapsulation portion 32 is relatively small, the area where the encapsulation portion 30 is not bonded to the protective film material 40 is relatively small. That is, the visual effect differences problem caused by the portion of the encapsulation portion 30 not bonding to the protective film material 40 in the display panel 01 is relatively small.

In an embodiment of the present disclosure, as shown in FIG. 11, FIG. 13 and FIG. 14, along the direction perpendicular to the plane of the display panel 01, the first encapsulation portion 31 overlaps with the light-emitting devices 20, and the second encapsulation portion 32 does not overlap with the light-emitting devices 20.

In some embodiments, even though the width of the first encapsulation portion 31 is greater than the width of the second encapsulation portion 32, since the first encapsulation portion 31 overlaps with the light-emitting devices 20, the presence of the first encapsulation portion 31 does not increase the bezel width of the display panel 01. In addition, even though the variations in the thickness of the first encapsulation portion 31 affects the light emitted from the light-emitting devices 20, since the curved surface of the first encapsulation portion 31 is smoother, the light emission effect of the first edge region R1 where the first encapsulation portion 31 is located does not exhibit abrupt changes, that is, the display effect of the first edge region R1 is relatively good.

In addition, the second encapsulation portion 32 does not overlap with the light-emitting devices 20, so that the impact of variations in the thickness of the encapsulation portion 30 on the light emission effect of the display panel 02 may be minimized.

FIG. 13 is a cross-sectional view taken along the C1-C2 direction in FIG. 1.

In an embodiment of the present disclosure, as shown in FIG. 13, the display panel 01 further includes the protective film material 40, and the protective film material 40 is disposed at a side of the encapsulation layer 30 away from the array substrate 10. The protective film material 40 and the encapsulation layer 30 may be bonded together by an optical adhesive. The protective film material 40 is used to protect the encapsulation layer 30.

In some embodiments, as shown in FIG. 13, the protective film material 40 is bonded to the first encapsulation portion 31 and not bonded to the second encapsulation portion 32. As shown in FIG. 13, the protective film material 40 bends in the first edge region R1 toward the surface of the first encapsulation portion 31 away from the array substrate 10 and is bonded to the surface of the first encapsulation portion 31 away from the array substrate 10. However, the protective film material 40 does not bend in the second border region R2 toward the first plane 320, but maintains substantially the same shape as the portion on the third encapsulation portion 33.

Since the width of the second encapsulation portion 32 is relatively small, the visual effect differences in the display panel 01 caused by the portion of the encapsulation portion 30 not bonded to the protective film material 40 is relatively small.

FIG. 14 is a cross-sectional view taken along the B1-B2 direction in FIG. 1.

In some embodiments, the display panel 01 further includes a filling layer 70. The filling layer 70 is in contact with at least the side surface of the array substrate 10 and the first plane 320 in the second edge region R2. Part of the filling layer 70 fills the gap between the array substrate 10 and the protective film material 40 in the second edge region R2. Since the protective film material 40 is not bonded to the first plane 320, the filling layer 70 may be provided on the side surface in the second edge region R2 to support the protective film material 40. The filling layer 70 in the second edge region R2 may be bonded to the protective film material to effectively support the protective film material 40 and prevent the protective film material 40 from warping in the second edge region R2.

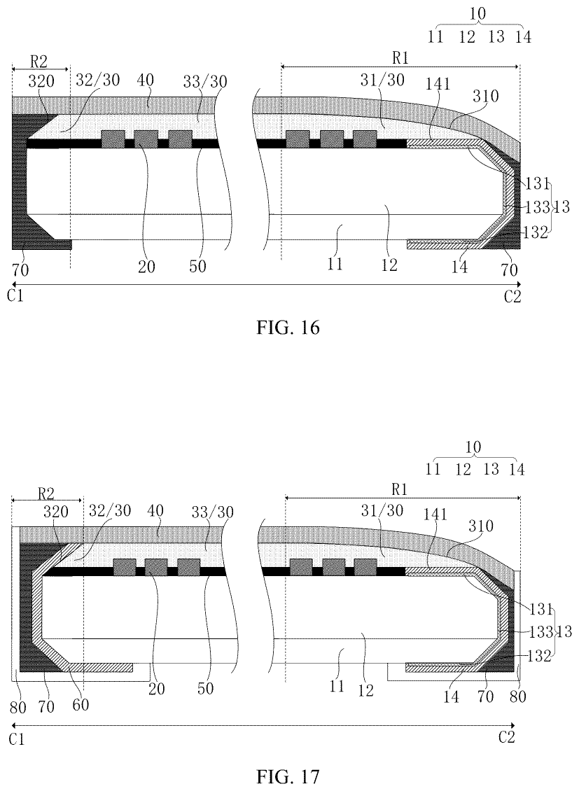

FIG. 15 is a cross-sectional view taken along the C1-C2 direction in FIG. 1, and FIG. 16 is a cross-sectional view taken along the C1-C2 direction in FIG. 1.

In addition, the filling layer 70 not only fills the gap between the array substrate 10 and the protective film material 40 in the second edge region R2, but may also fill the gap between the array substrate 10 and the protective film material 40 in the first edge region R1.

For example, as shown in FIG. 15 and FIG. 16, the filling layer 70 is at least in contact with the side surface of the second layer 14 in the first edge region R1, and a part of the filling layer 70 fills the gap between the second layer 14 and the protective film material 40.

In a technical solution, as shown in FIG. 15, the first edge region R1 may include the second layer 14 and the filling layer 70, and the second edge region R2 may include the third layer 60 and the filling layer 70.

In a technical solution, as shown in FIG. 16, the first edge region R1 may include the second layer 14 and the filling layer 70, and the second edge region R2 may not include the third layer 60 but include the filling layer 70. When the second edge region R2 does not include the third layer 60, the width of the second edge region R2 may be minimized.

In some embodiments, the filling layer 70 is a light-shielding layer. The filling layer 70 minimizes the probability that reflective structures, such as metal, in the edge region of the display panel 01 are perceived by the human eye.

In some embodiments, the filling layer 70 is a light-transmitting structure.

FIG. 17 is a cross-sectional view taken along the C1-C2 direction in FIG. 1.

In a technical solution corresponding to this embodiment of the present disclosure, as shown in FIG. 17, the display panel 01 further includes an electrostatic conductive layer 80. At least a part of the electrostatic conductive layer 80 is disposed at a side of the filling layer 70 adjacent to the edge of the display panel 01. The electrostatic conductive layer 80 may be a light-shielding layer. Furthermore, the electrostatic conductive layer 80 may include a low-electrical resistance ink. For example, the electrostatic conductive layer 80 may be made of low-electrical resistance ink.

The electrostatic conductive layer 80 may reduce the risk of static electricity outside the display panel 01 entering the interior of the display panel 01 through the side surface. When the filling layer 70 is a light-transmitting structure, the electrostatic conductive layer 80 is a light-shielding layer, which may minimize the probability of reflective structures, such as metal, in the edge area of the display panel 01 being perceived by the human eye.

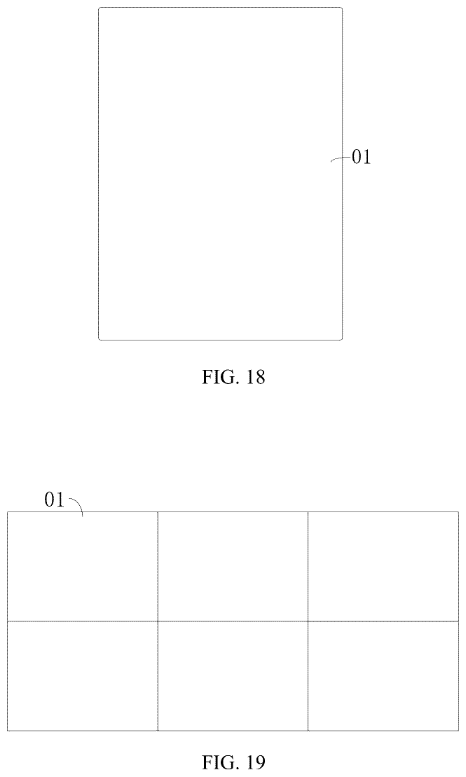

FIG. 18 is a schematic diagram of a display apparatus according to an embodiment of the present disclosure, and FIG. 19 is a schematic diagram of a display apparatus according to an embodiment of the present disclosure.

Based on the same inventive concept, an embodiment of the present disclosure further provides a display apparatus. As shown in FIG. 18, the display apparatus includes the above display panel 01. The display apparatus shown in FIG. 18 is merely for illustration purposes, and the display apparatus may be any electronic device with a display function, such as a mobile phone, tablet computer, laptop computer, e-book, or television.

Based on the same inventive concept, an embodiment of the present disclosure further provides a spliced display apparatus. As shown in FIG. 19, the display apparatus is a spliced display apparatus including the above display panel 01. At least portions of the first edge region R1 and the second edge region R2 of the display panel 01 may be its splicing regions, and the splicing regions are the edge regions of the display panel 01 when spliced with the adjacent display panel 01. Such spliced display apparatus may be a large spliced screen and may be applied in public information display (PID) scenarios, such as stations and airports. When the spliced display apparatus includes the above display panel 01, it simultaneously takes into account the anti-static requirements and splicing gap width at different positions of the display apparatus, thereby improving the display effect of the spliced display apparatus.

What is claimed is:

1. A display panel, comprising a first edge region, a second edge region, an array substrate, a plurality of light-emitting devices disposed at a side of the array substrate, and an encapsulation layer disposed at a side of the plurality of light-emitting devices away from the array substrate;
wherein the array substrate comprises a substrate and a side trace;
wherein the side trace comprises a first portion and a second portion electrically connected to each other, wherein the first portion is disposed at a side of the substrate facing the encapsulation layer, and the second portion is disposed at a side of the substrate away from the encapsulation layer;
wherein the side trace is disposed in the first edge region; and
wherein the encapsulation layer comprises a first encapsulation portion and a second encapsulation portion, the first encapsulation portion is disposed in the first edge region, the second encapsulation portion is disposed in the second edge region, and the first encapsulation portion has a different shape from the second encapsulation portion.

2. The display panel according to claim 1, wherein:
a width of the first encapsulation portion in a direction parallel to a plane of the substrate is greater than a width of the second encapsulation portion in the direction parallel to the plane of the substrate.

3. The display panel according to claim 1, wherein:
along a direction perpendicular to a plane of the display panel, the first encapsulation portion overlaps with the light-emitting devices, and the second encapsulation portion does not overlap with the light-emitting devices.

4. The display panel according to claim 1, wherein:
a surface of the first encapsulation portion away from the array substrate is an arc-shaped surface.

5. The display panel according to claim 4, wherein:
the encapsulation layer further comprises a third encapsulation portion, the third encapsulation portion is disposed at respective sides of the first edge region and the second edge region away from an edge of the display panel; and
the first encapsulation portion has a width W1 in a direction parallel to a plane of the substrate, and the third encapsulation portion has a thickness H1 in the direction perpendicular to the plane of the substrate, where W1 is greater than or equal to 10*H1.

6. The display panel according to claim 4, wherein:
the array substrate comprises a first layer, the first layer is disposed between the encapsulation layer and the substrate; the first encapsulation portion is in contact with the first layer, and an edge of the first encapsulation portion adjacent to an edge of the display panel is in contact with the first layer.

7. The display panel according to claim 6, wherein:
the first layer comprises a light-shielding structure, and the light-shielding structure is disposed at least between adjacent light-emitting devices.

8. The display panel according to claim 4, wherein:
the array substrate comprises a second layer, the second layer is in contact with a surface of the side trace away from the substrate; and
at least a part of the first encapsulation portion is in contact with the second layer.

9. The display panel according to claim 8, wherein:
the second layer comprises a third portion, the third portion is disposed between the substrate and the encapsulation layer; and
an edge of the third portion away from an edge of the display panel is disposed at a side of the first encapsulation portion away from the edge of the display panel.

10. The display panel according to claim 8, wherein:
the array substrate comprises a first layer, and the first layer is disposed between the encapsulation layer and the substrate;
the second layer comprises a third portion, and the third portion is disposed between the substrate and the encapsulation layer; and
the first encapsulation portion comprises a first encapsulation sub-portion and a second encapsulation sub-portion, wherein the second encapsulation sub-portion is disposed at a side of the first encapsulation sub-portion adjacent to an edge of the display panel, wherein the first encapsulation sub-portion is in contact with the first layer, and wherein the second encapsulation sub-portion is in contact with the third portion.

11. The display panel according to claim 9, wherein:
the first portion has a thickness H4 in a direction perpendicular to a plane of the substrate, and the third portion has a thickness H5 in the direction perpendicular to the plane of the substrate, where H5>H4.

12. The display panel according to claim 1, wherein:
a surface of the second encapsulation portion facing an edge of the display panel is an inclined first plane.

13. The display panel according to claim 12, wherein:
in the second edge region, an angle of 90° is formed between a surface of the substrate facing the encapsulation layer and a side surface of the substrate.

14. The display panel according to claim 13, wherein:
in the second edge region, a surface, facing the edge of the display panel, of at least a part of layers of the array substrate disposed at the side of the substrate facing the encapsulation layer is an inclined second plane, and an angle α is formed between the inclined second plane and the substrate.

15. The display panel according to claim 12, wherein:
the array substrate comprises a second layer, the display panel further comprises a third layer, the second layer is in contact with a surface of the first portion away from the substrate, and the third layer is in contact with at least a side surface of the array substrate in the second edge region and the inclined first plane; and
the third layer and the second layer are made of a same material, and the second layer and the third layer are light-shielding layers.

16. The display panel according to claim 12, further comprising a protective film material disposed at a side of the encapsulation layer away from the array substrate;
wherein the protective film material is bonded to the first encapsulation portion and wherein the protective film material is not bonded to the second encapsulation portion.

17. The display panel according to claim 16, further comprising a filling layer;
wherein the filling layer is in contact with at least a side surface of the array substrate in the second edge region and the inclined first plane, and a part of the filling layer fills a gap between the array substrate in the second edge region and the protective film material.

18. The display panel according to claim 17, wherein:
the filling layer is a light-shielding layer or a light-transmitting structure.

19. The display panel according to claim 18, further comprising an electrostatic conductive layer;
wherein at least a part of the electrostatic conductive layer is disposed at a side of the filling layer adjacent to the edge of the display panel; and the electrostatic conductive layer is a light-shielding layer.

20. A display apparatus, comprising a display panel, wherein the display panel comprises a first edge region, a second edge region, an array substrate, a plurality of light-emitting devices disposed at a side of the array substrate, and an encapsulation layer disposed at a side of the plurality of light-emitting devices away from the array substrate;
wherein the array substrate comprises a substrate and a side trace, the side trace comprises a first portion and a second portion electrically connected to each other, the first portion is disposed at a side of the substrate facing the encapsulation layer, and the second portion is disposed at a side of the substrate away from the encapsulation layer;
wherein the side trace is disposed in the first edge region; and
wherein the encapsulation layer comprises a first encapsulation portion and a second encapsulation portion, the first encapsulation portion is disposed in the first edge region, the second encapsulation portion is disposed in the second edge region, and the first encapsulation portion has a different shape from the second encapsulation portion.
